(19) United States
(12) Patent Application Publication
(10) Pub. No.: US 2007/0195500 A1
(43) Pub. Date: Aug. 23, 2007

(54) HEAT DISSIPATION APPARATUS

(75) Inventors: NIEN-TIEN CHENG, Tu-Cheng (TW); CHEN-SHEN LIN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Taipei Hsien (TW)

(21) Appl. No.: 11/309,370

(22) Filed: Aug. 1, 2006

(30) Foreign Application Priority Data
Feb. 22, 2006 (CN) 200610033923.2

(51) Int. Cl. H05K 7/20; F28D 15/00; H01L 23/34

(52) U.S. Cl. 361/697; 361/704; 165/104.33; 361/185; 257/718

(57) ABSTRACT

A heat dissipation apparatus includes a metal enclosure for an electronic device, at least one heat pipe secured to the enclosure, a fin assembly secured to the enclosure, a centrifugal blower secured to the enclosure for promoting heat dissipation for the fin assembly. The heat pipe has an evaporating section thermally connecting with a heat generating electronic component within the enclosure, and first and second condensing sections respectively connecting with the enclosure and the fin assembly. The enclosure absorbs and dissipates heat generated by the heat generating electronic component. The heat dissipation surface area is increased and as a result the heat dissipation efficiency of the heat dissipation apparatus is improved.

### 1. FIELD OF THE INVENTION

The present invention relates generally to a heat dissipation apparatus, and more particularly to a heat dissipation apparatus for dissipating heat generated by heat generating electronic components enclosed in a system enclosure, wherein the apparatus has at least one heat pipe secured to the enclosure for dissipating heat via the enclosure.

### 2. DESCRIPTION OF RELATED ART

It is well known that heat is produced by electronic components such as integrated circuit chips during their normal operations. If the heat is not timely removed, these electronic components may overheat. Therefore, heat dissipation apparatuses are often used to cool these electronic components.

As an example, a conventional heat dissipation apparatus generally includes a plate, a fin assembly having a plurality of fins, a fan creating an airflow over the fin assembly, and a heat pipe having an evaporating section for holding in thermal contact with a heat generating electronic component such as a central processing unit (CPU) of a computer, and a condensing section to which the fin assembly is attached. The fin assembly and the fan are disposed on the plate, and then the plate together with the fin assembly and the fan is secured to an enclosure of the computer. The heat pipe transfers heat from the heat generating electronic component which is thermally connected with the evaporating section thereof, to the fin assembly which is attached to the condensing section of the heat pipe. The heat is then dissipated into the ambient atmosphere via the airflow flowing over the fin assembly.

However, the heat dissipation apparatus dissipates the heat only by making use of the fin assembly. Thus, the heat dissipation surface area is relatively small and the heat dissipation efficiency of the heat dissipation apparatus is accordingly reduced. Furthermore, the conventional heat dissipation apparatus increases the weight of the computer, and generates vibration and noise during operation thereof since it is a separate module from the enclosure of the computer.

Therefore, it is desirable to provide a heat dissipation apparatus which can overcome the above-mentioned disadvantages.

### SUMMARY OF THE INVENTION

The present invention relates to a heat dissipation apparatus for dissipating heat generated by a heat generating electronic component. According to a preferred embodiment of the present invention, the heat dissipation apparatus includes at least one heat pipe, a fin assembly, a centrifugal blower for promoting heat dissipation in the fin assembly, and an enclosure made of thermally conductive material. The heat pipe has an evaporating section thermally connecting with the heat generating electronic component, and first and second condensing sections respectively connecting with the enclosure and the fin assembly. The enclosure absorbs and helps to dissipate the heat generated by the heat generating electronic component. The heat dissipation surface area is thus increased and as a result the heat dissipation efficiency of the heat dissipation apparatus is improved. Furthermore, since the heat dissipation apparatus is directly secured to the enclosure, weight of the heat dissipation apparatus and accordingly weight of a computer including the heat dissipation apparatus can be reduced. Moreover, a vibration and noise produced by operation of the heat dissipation apparatus can be lowered.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present heat dissipation apparatus can be better understood with reference to the following drawings. The components in the drawings are not necessarily drawn to scale, the emphasis instead being placed upon clearly illustrating the principles of the present heat dissipation apparatus. Moreover, in the drawings, like reference numerals designate corresponding parts throughout the several views.

FIG. 1 is an assembled, isometric view of a heat dissipation apparatus in accordance with a preferred embodiment of the present invention;

FIG. 2 is an exploded, isometric view of the heat dissipation apparatus of FIG. 1; and

FIG. 3 is an enlarged view of the circled portion III of the heat dissipation apparatus of FIG. 1.

### DETAILED DESCRIPTION OF THE INVENTION

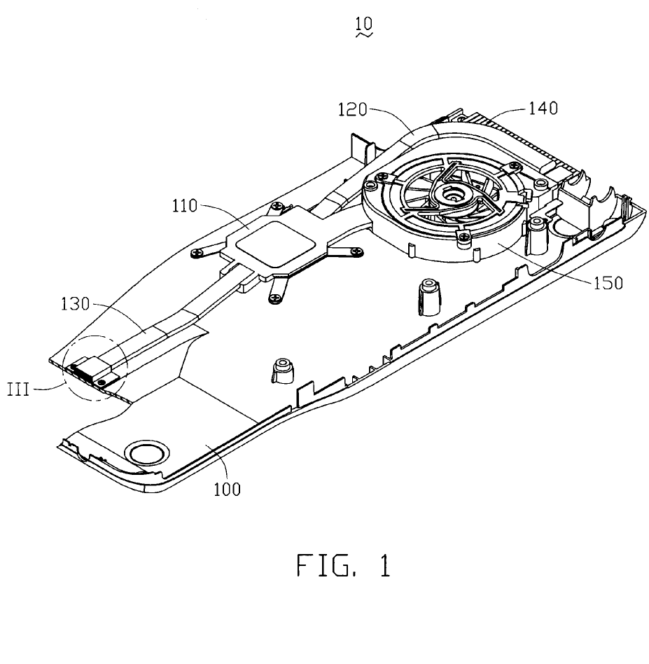

Referring to FIG. 1, a heat dissipation apparatus 10 according to a preferred embodiment of the present invention is shown. The heat dissipation apparatus 10, which is attached to a computer enclosure 100 having good heat conduction, includes a heat spreader 110 for thermally connecting with a heat generating electronic component (not labeled) in the computer enclosure 100, two heat pipes 120, 130, a fin assembly 140 contacting with the computer enclosure 100, and a centrifugal blower 150 producing an airflow over the fin assembly 140.

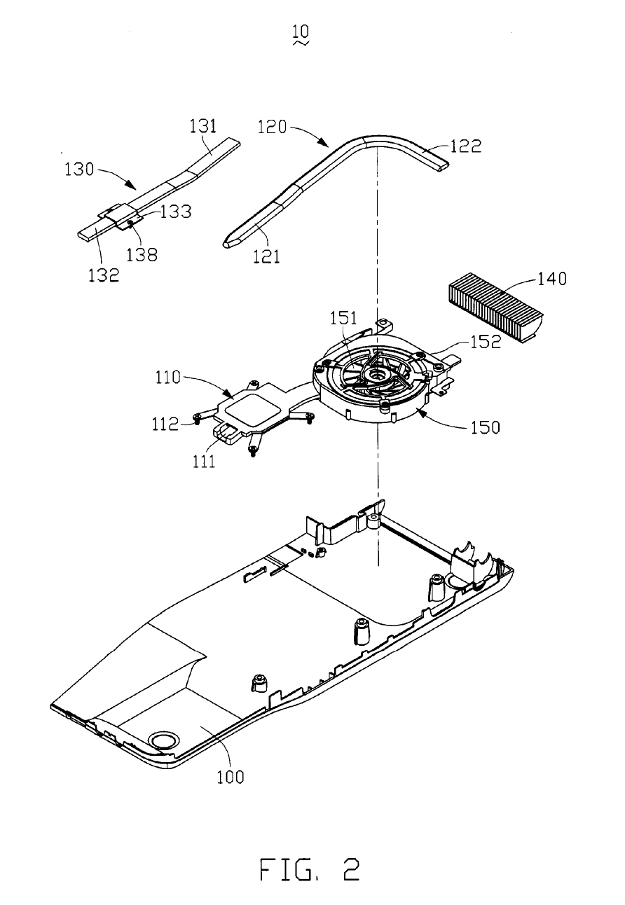

FIG. 2 shows the heat dissipation apparatus 10 in an exploded view. The computer enclosure 100 is typically made of a highly thermally conductive material such as copper, aluminum, magnesium or their alloys. The heat spreader 110, which is directly secured to the computer enclosure 100 via a plurality of first screws 112, thermally connects with the heat generating electronic component in the computer enclosure 100 and defines a receiving-groove 111 therein for receiving the two heat pipes 120, 130 therein.

The two heat pipes 120, 130 are flattened so as to increase the surface area contacting the fin assembly 140 and the enclosure 100. The heat pipes 120, 130 each include respective evaporating sections 121, 131. The evaporating sections 121, 131 are each received in one of two ends of the receiving-groove 111 of the heat spreader 110. The heat pipes 120, 130 also each include respective condensing sections 122, 132. The condensing section 122 thermally connects with a flat top surface of the fin assembly 140 and the condensing section 132 is secured to the computer enclosure 100 for directly contacting therewith. Alternatively, the heat pipes 120, 130 can be substituted with a single heat pipe, the single heat pipe having an evaporating section at a middle thereof for being received in the receiving-groove 111 of the heat spreader 110, and two condensing sections at two respective ends thereof. One of two condensing sections is directly secured to the computer enclosure 100 and the other thermally connected with the flat top surface of the fin assembly 140.

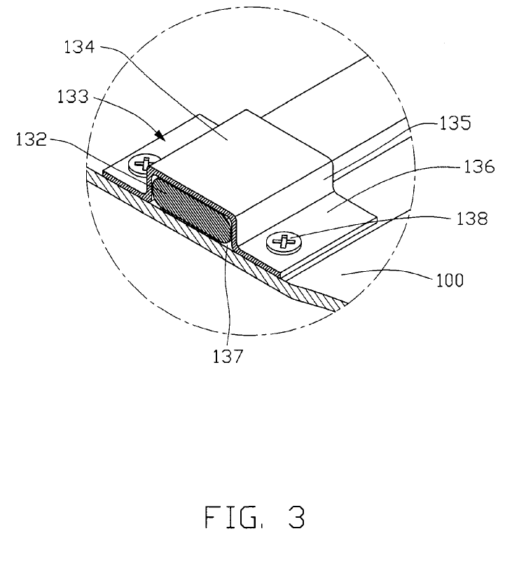

Referring to FIG. 3, the condensing section 132 of the heat pipe 130 is directly secured to the computer enclosure 100 via a spring bracket 133, which in turn is secured by two second screws 138 engaging with the enclosure 100. The spring bracket 133 has a U-shaped cross section and includes a flat contacting portion 134, two sidewalls 135 descending from the contacting portion 134, and two wings 136 horizontally extending from the sidewalls 135. A receiving-channel 137 is thus formed between the contacting portion 134 and the two sidewalls 135 for receiving the condensing section 132 of the heat pipe 130 therein. A layer of thermal interface material (not labeled), such as thermal grease, is arranged at the contacting surfaces between a bottom surface of the condensing section 132 of the heat pipe 130 and the computer enclosure 100, for improving the heat conduction efficiency of the heat dissipation apparatus 10. Alternatively, the condensing section 132 of the heat pipe 130 can be directly attached to the computer enclosure 100 via metallurgical means such as soldering, sintering and so on.

Referring back to FIGS. 1-2, the centrifugal blower 150 has an air inlet 151 at a top surface thereof, and an air outlet 152 at a lateral side thereof, wherein the airflow produced by the centrifugal blower 150 flows from the air inlet 151 towards the air outlet 152. The fin assembly 140 is disposed near to the air outlet 152 of the centrifugal blower 150, with the flat bottom surface of the fin assembly 140 thermally contacting with the computer enclosure 100. The airflow coming from the air outlet 152 of the centrifugal blower 150 flows over the fin assembly 140, thus dissipating heat from the fin assembly 140 into the ambient atmosphere. The centrifugal blower 150 can be directly secured to the enclosure 100 via fasteners such as screws.

In the present heat dissipation apparatus 10, the heat pipes 120, 130 transfer heat generated by the heat generating electronic component from the heat spreader 110 thermally connecting with the heat generating electronic component both to the fin assembly 140 and to the computer enclosure 100. In this way a part of the heat is dissipated into the ambient atmosphere via the fin assembly 140, and another part of the heat is dissipated via the computer enclosure 100. Accordingly, the heat dissipation surface area is increased and the heat dissipation efficiency of the heat dissipation apparatus 10 is improved. Furthermore, since the present heat dissipation apparatus 10 is directly screwed onto the enclosure 100, noise and vibration during operation of the heat dissipation apparatus 10 can be lowered. Moreover, weight of the present heat dissipation apparatus 10 can be reduced in comparison with the conventional art since the plate of the conventional art for carrying the components of the heat dissipation apparatus thereon can be omitted in the present heat dissipation apparatus.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus comprising:
an enclosure made of a thermally conductive material;
a fin assembly secured to the enclosure;
a centrifugal blower secured to the enclosure and producing an airflow flowing over the fin assembly; and
a heat pipe secured to the enclosure, having an evaporating section at a middle portion thereof adapted for thermally connecting with a heat generating electronic component, and first and second condensing sections at first and second ends thereof respectively, wherein the first condensing section thermally connects with the fin assembly while the second condensing section thermally connects with the enclosure.

2. The heat dissipation apparatus of claim 1, wherein the enclosure is made of copper, aluminum, magnesium or their alloys.

3. The heat dissipation apparatus of claim 1, wherein the evaporating section of the heat pipe is attached to a heat spreader, and the heat spreader is secured to the enclosure.

4. The heat dissipation apparatus of claim 1, wherein the second condensing section of the heat pipe is secured to the enclosure via a spring bracket.

5. The heat dissipation apparatus of claim 4, wherein the spring bracket includes a flat contacting portion, two sidewalls descending from the contacting portion, and two wings extending from the sidewalls, wherein a receiving-channel is formed between the contacting portion and the two sidewalls for receiving the second condensing section of the heat pipe therein.

6. The heat dissipation apparatus of claim 4, wherein a layer of thermal interface material is provided at the contacting surfaces between a bottom surface of the second condensing section of the heat pipe and the enclosure.

7. The heat dissipation apparatus of claim 1, wherein the second condensing section of the heat pipe is attached to the enclosure via one of soldering and sintering.

8. The heat dissipation apparatus of claim 1, wherein the fin assembly and the centrifugal blower are directly secured to the enclosure.

9. A heat dissipation apparatus comprising:
an enclosure made of thermally conductive material;
a fin assembly located within and secured to the enclosure;
a centrifugal blower secured to the enclosure and producing an airflow flowing over the fin assembly; and
first and second heat pipes secured to the enclosure, each of the first and second heat pipes having a condensing section and an evaporating section adapted for thermally connecting with a heat generating electronic component, wherein the condensing section of the first heat pipe connects with the fin assembly while the condensing section of the second heat pipe connects with the enclosure.

10. The heat dissipation apparatus of claim 9, wherein the evaporating sections of the first and second heat pipes are received in at least one groove defined in a heat spreader, and the heat spreader is secured to the enclosure and adapted for thermally connecting with the heat generating electronic component.

11. The heat dissipation apparatus of claim 9, wherein the condensing section of the second heat pipe is secured to the enclosure via a spring bracket.

12. The heat dissipation apparatus of claim 11, wherein the spring bracket includes a flat contacting portion, two sidewalls descending from the contacting portion, and two wings extending from the sidewalls, wherein a receiving-channel is formed between the contacting portion and the two sidewalls for receiving the condensing section of the second heat pipe therein.

13. The heat dissipation apparatus of claim 11, wherein a layer of thermal interface material is provided on the contacting surfaces between a bottom surface of the condensing section of the second heat pipe and the enclosure.

14. The heat dissipation apparatus of claim 9, wherein the condensing section of the second heat pipe is attached to the enclosure via one of soldering and sintering.

15. The heat dissipation apparatus of claim 9, wherein the fin assembly and the centrifugal blower are directly secured to the enclosure.

16. A heat dissipation apparatus comprising:
a metal enclosure for an electronic device;
a heat spreader adapted for thermally connecting with a heat generating electronic component of the electronic device, the heat spreader being secured to the metal enclosure;
a heat transfer device having a first portion sandwiched between the metal enclosure and the heat spreader and thermally connecting with the heat spreader for receiving heat from the heat spreader, and a second portion secured to the enclosure and thermally connecting with the enclosure for dissipating the heat to the enclosure.

17. The heat dissipation apparatus of claim 16, wherein the heat transfer device is a heat pipe, the first portion is an evaporating portion at a middle of the heat pipe, the second portion is a condensing portion at a first end of the heat pipe, the heat dissipation apparatus further comprising a fin assembly secured to the enclosure, the heat pipe having a second end thermally connecting with the fin assembly.

18. The heat dissipation apparatus of claim 16, wherein the heat transfer device consists of two heat pipes, the first portion is an evaporating portion of one of the heat pipes, the second portion is a condensing portion of the one of the heat pipes, the heat dissipation apparatus further comprising a fin assembly secured to the enclosure, the other one of the two heat pipes having an evaporating portion sandwiched between the heat spreader and the enclosure and thermally connecting with the heat spreader and a condensing portion thermally connecting with the fin assembly.

19. The heat dissipation apparatus of claim 17, wherein the first end of the heat pipe is secured to the enclosure by a spring bracket having a U-shaped cross section.

20. The heat dissipation apparatus of claim 18, wherein the condensing portion of the one of the heat pipes is secured to the enclosure by a spring bracket having a U-shaped cross section.
